(19) United States
(12) Patent Application Publication
(10) Pub. No.: US 2009/0137096 A1
(43) Pub. Date: May 28, 2009

(54) Clamp ring for wafer and method of manufacturing semiconductor apparatus

(75) Inventor: Ryuji Tomita, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/289,740

(22) Filed: Nov. 3, 2008

(30) Foreign Application Priority Data
Nov. 28, 2007 (JP) 2007-307512

(51) Int. Cl. H01L 21/30; B25B 5/00; B23Q 3/06

(52) U.S. Cl. 438/455; 269/315; 269/319; 257/E21.211

(57) ABSTRACT

A clamp ring includes an abutting part abutting on the entire outer periphery of the main surface of a wafer when the wafer is fixed, and a brim part extending from the upper part of the abutting part to the inside of the wafer and provided so as not to abut on the main surface even when the wafer is fixed. The abutting part includes a first abutting section and a second abutting section, and a width of the first abutting section in a radial direction is greater than the width of the second abutting section in a radial direction.

### BACKGROUND OF THE INVENTION

1. Field of the Invention

The present invention relates to a clamp ring for fixing a wafer, and in particular, to a clamp ring for fixing a wafer, which is used in a process for depositing a film on a wafer.

2. Description of Related Art

In a semiconductor apparatus manufacturing process, various processes are performed on a semiconductor wafer (hereinafter, simply referred to as a “wafer”). In general, processes on a wafer are performed while the wafer is fixed. Techniques using a clamp ring to fix a wafer are known. When a clamp ring is used, first, the main surface of a wafer, which is a surface to be processed, is positioned to face upward, and is placed on a stage. Then, the outer periphery of the main surface is physically pressed by using a clamp ring. In this way, the wafer is fixed between the clamp ring and the stage by the clamp ring and the stage.

If a wafer is fixed by using a clamp ring, then an area of a main surface of a wafer pressed by the clamp ring is covered by the clamp ring. As a result, no processes can be performed on such an area, which reduces a processible area. For this reason, it is required to create a technique capable of fixing a wafer without limiting a processible area.

In association with the above, a clamp ring for fixing a wafer which is installed in an etching apparatus is disclosed in Patent Document 1. This clamp ring fixes a wafer, and includes a clamp ring main body whose inner diameter is smaller than the outer diameter of the wafer and a plurality of rectangular projections which are disposed along the inner edge of the clamp ring main body. In Patent Document 1, it is disclosed that, since the rectangular projections fix a wafer without resting on an available device area, the available device area is not wasted.

Meanwhile, the processes performed on a wafer include a process for depositing a film on a main surface of a wafer. Sputter film deposition process can be used as an example of the film depositing process. If a wafer is fixed by the clamp ring and a film depositing process is performed on the wafer, then a film may be deposited even on the clamp ring and conglutinate the wafer and the clamp ring. If the wafer and the clamp ring are conglutinated together, then when the clamp ring is separated from the wafer, for example, a crack of the wafer may occur.

A technique for preventing conglutination of a wafer and a clamp ring is disclosed in Patent Document 2. In Patent Document 2, there is disclosed a clamp which includes an abutting surface that abuts on the outer periphery of a surface of a semiconductor wafer, a brim part extending from the upper part of the abutting surface to the inside of the semiconductor wafer, and a spring part disposed outside the abutting surface and having an end part is positioned below the abutting surface. According to Patent Document 2, there is disclosed that, after film deposition is completed, the clamp ring and the semiconductor wafer are separated from each other by the spring part and conglutination of the clamp ring and the semiconductor wafer can thus be prevented. Further, there is disclosed that abutting surfaces are provided at 4 parts of the clamp ring and any part other than the abutting surfaces is not in contact with the wafer.

In addition, when a wafer is fixed by a clamp ring, since the clamp ring presses a wafer, a crack or a defect (chipping) of the wafer may occur. A technique for preventing such chipping is disclosed in Patent Document 3. In Patent Document 3, there is disclosed a technique of using titanium as a major component of a clamp ring. According to that technique, the weight of a clamp ring can be reduced, stress applied to a wafer can be reduced, and chipping can be prevented. Furthermore, in Patent Document 3, there is disclosed that, an outer peripheral area of a wafer pressed by the clamp ring is made to be within 3.5 mm from the outer circumferential edge of the wafer, thereby capable of increasing the number of chips acquirable from one wafer.

[Patent Document 1] Japanese Unexamined Patent Application Publication No. 2000-58630

[Patent Document 2] Japanese Unexamined Patent Application Publication No. 2004-221134

[Patent Document 3] Japanese Unexamined Patent Application Publication No. 2005-120410

### SUMMARY

The technique disclosed in Patent Document 1 is a technique related to an etching apparatus. Therefore, it is not even considered that, when a film depositing process is performed, the clamp ring and the wafer may be conglutinated together.

As described in Patent Document 2, it is possible to prevent conglutination of the clamp ring and the wafer by providing the brim. Here, in order to prevent the conglutination more reliably, it can be considered to increase the width of the brim. However, if the width of the brim increases, then a film depositing area of the main surface of the wafer is limited. Further, in Patent Document 2, an abutting surface is not provided over the entire outer periphery of the wafer and a portion of the outer periphery of the wafer does not abut on the abutting surface. In such a portion, a deposited film may spread to the stage side and the stage may thus become contaminated.

In addition, in Patent Document 3, in order to ensure a film depositing area, the width of a portion of the wafer pressed by the clamp ring is made to be 3.5 mm or less. However, if the width of the portion of the wafer pressed is small, for example, then misalignment when the wafer is transferred onto the stage (hereinafter, referred to as transfer misalignment) makes it easily possible for the clamp to deviate from the wafer. Further, since it becomes easy for the edge of the wafer to be locally weighted, the risk of chipping increases. Furthermore, measures against conglutination of the clamp ring and the wafer are not particularly disclosed.

Therefore, a film depositing process requires a technique that is capable of reliably fixing a wafer while preventing chipping and conglutination of a wafer and a clamp ring without limiting a film depositing area.

A clamp ring for a wafer according to an exemplary embodiment of the present invention is a clamp ring for a wafer which presses a wafer from a main surface side to fix the wafer when a film is deposited on the main surface of the wafer. The clamp ring includes an abutting part abutting on the entire outer periphery of the main surface when the wafer is fixed, and a brim part extending from the upper part of the abutting part to the inside and provided such that it doses not abut on the main surface even when the wafer is fixed. Here, the abutting part includes a first abutting section and a second abutting section. As for the width of the abutting part in a radial direction, the width of the first abutting section is greater than the width of the second abutting section.

According to the above-mentioned structure, the brim parts prevent conglutination of the wafer and the clamp ring. Further, when the wafer is fixed, local force is not applied between the wafer and the clamp ring by the first abutting section having the greater width in a radial direction. Therefore, it is possible to prevent chipping. Furthermore, it is possible to reliably fix the wafer by the first abutting section. In addition, since the second abutting section has the smaller width in a radial direction, it is possible to sufficiently ensure a film depositing area. Also, because the abutting part is provided to correspond to the entire outer periphery of the wafer, when a film is deposited, the film does not spread to the stage side. Therefore, it is possible to prevent the stage from being contaminated.

A method of manufacturing a semiconductor apparatus according to an embodiment of the present invention includes a process for fixing a wafer by using the above-mentioned clamp ring for a wafer, and a depositing process for depositing a film on a main surface of the fixed wafer.

According to the embodiment of the present invention, a clamp ring for a wafer is provided which can reliably fix the wafer while preventing chipping and conglutination of a wafer and the clamp ring in a film depositing process without limiting a film depositing area.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a plan view of a clamp ring;

FIG. 2 is a sectional view illustrating a structure when a wafer is fixed by the clamp ring;

FIG. 3 is a sectional view illustrating a structure of a first fixing section; and

FIG. 4 is a sectional view illustrating a structure of a second fixing section.

### DETAILED DESCRIPTION OF THE EXEMPLARY EMBODIMENTS

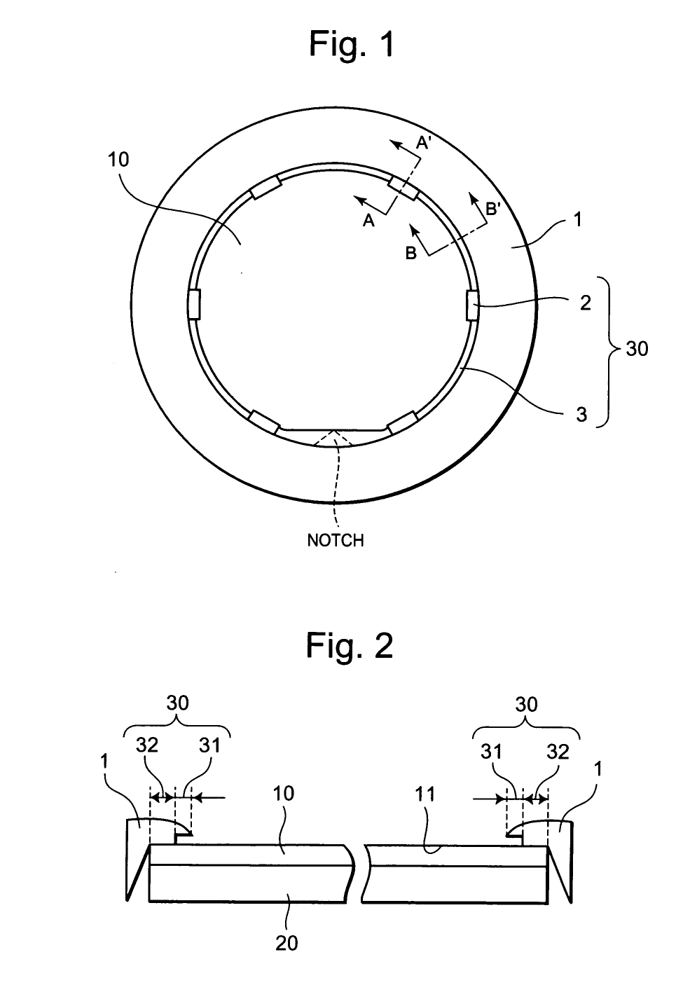

FIG. 1 is a top view illustrating a state when a wafer 10 is fixed by a clamp ring according to a exemplary embodiment, and FIG. 2 is a sectional view illustrating the state when the wafer 10 is fixed by the clamp ring according to the exemplary embodiment. The clamp ring is used to fix a wafer in a film depositing process. In the exemplary embodiment, a sputtering process is described as an example of the film depositing process.

As shown in FIG. 1, the clamp ring includes a clamp ring main body 1 and a fixing part 30.

The clamp ring main body 1 is ring-shaped. The inner periphery of the clamp ring main body 1 has a shape corresponding to the outer periphery of the wafer 10.

The fixing part 30 is a part for pressing the wafer 10. The fixing part 30 extends from the inner periphery of the clamp ring main body 1 towards the inside (the center of a wafer when the wafer is fixed). The fixing part 30 is provided to correspond to the entire inner periphery of the clamp ring main body 1.

As shown in FIG. 2, the fixing part 30 includes an abutting part 32 and a brim part 31. The abutting part 32 is a part which abuts on a main surface 11 of a wafer. A wafer 10 is placed on a stage 20 to expose the main surface 11. The outer periphery of the main surface 11 abuts on the abutting part 32 of the clamp ring and is pressed by the clamp ring. Therefore, the wafer 10 is fixed between the stage 20 and the clamp ring by the stage 20 and the clamp ring.

The brim part 31 is provided to prevent the wafer 10 and the clamp ring from being conglutinated due to a deposited film. The brim part 31 extends from the upper part of the abutting part 32 towards the inside (the center of the main surface 11) in parallel with the main surface 11. Therefore, the brim part 31 does not abut on the main surface 11.

As shown in FIG. 1, the fixing part 30 is composed of first fixing sections 2 and second fixing sections. Plural (for example, six) first fixing sections 2 are provided. Sections other than the first fixing sections 2 of the fixing part 30 are the second fixing sections 3.

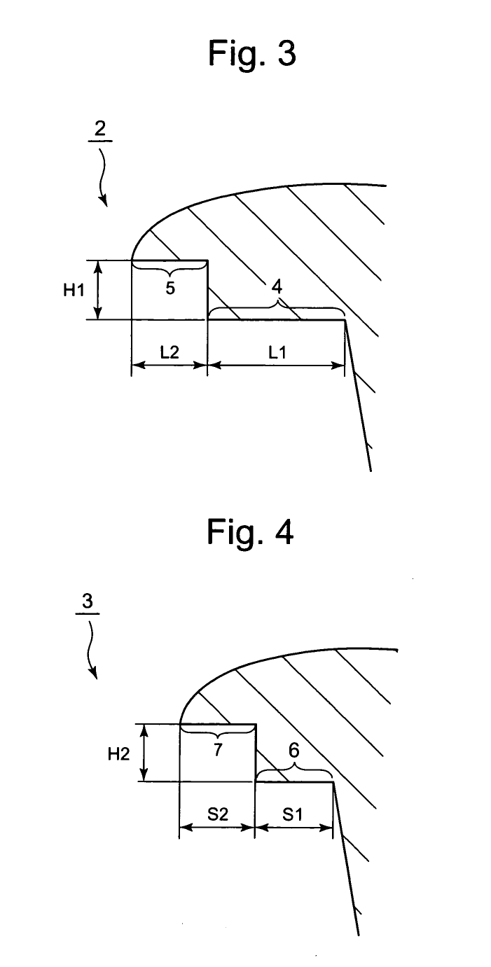

FIG. 3 is a sectional view taken along the line A-A′ of FIG. 1 and shows the sectional structure of the clamp ring in a first fixing section 2. Further, FIG. 4 is a sectional view taken along the line B-B′ of FIG. 1 and shows the sectional structure of the clamp ring in a second fixing section 3.

As shown in FIGS. 3 and 4, the width L1 of the abutting part in the first fixing section 2 (hereinafter, referred to as a first abutting section 4) is equal to or greater than 1.5 mm (in particular, 1.8 mm) and is less than or equal to 5.0 mm. Further, the width S1 of the abutting part in the second fixing section 3 (hereinafter, referred to as a second abutting section 6) is equal to or greater than 0.3 mm and is less than 1.5 mm (in particular, 1.0 mm). In conclusion, the width of the first abutting section 4 is greater than that of the second abutting section-6. Furthermore, the width L1 and the width S1 are widths of the abutting sections in a radial direction (the normal direction to the inner periphery shape of the clamp ring).

It is preferable that the length of a portion of the entire inner periphery of the clamp ring provided with the first fixing section 2 be 50% or less of the entire inner periphery. If the length of the portion provided with the first fixing section 2 exceeds 50%, the film depositing area tends to be reduced.

Further, as shown in FIG. 3, assuming that the width of the brim part in the first fixing section 2 (hereinafter, referred to as a first brim section 5) is L2 and the height of the first brim section 5 (a distance from a main surface 11 of a fixed wafer to the brim section 5) is H1, the first brim section 5 is provided so that it meets the condition of “2.5×H1≦L2≦25×H1”. In particular, H1 is 0.2 mm and the width L2 is 1.0 mm.

Furthermore, as shown in FIG. 4, assuming that the width of the brim part in the second fixing section 3 (hereinafter, referred to as a second brim section 7) is S2 and the height of the second brim section 7 is H2, the second brim section 7 is provided so that it meets the condition of “2.5×H2≦S2≦25×H2”. In particular, H2 is 0.2 mm and the width S2 is 1.0 mm. In the second fixing section 3, since the width of the second abutting section 6 is small (1.0 mm), even though a wafer is aligned with the second brim section 7, the second fixing section 3 overlaps the wafer by only 2 mm.

As described above, when a wafer is fixed by the clamp ring, the first abutting sections 4 of the plurality of first fixing sections 2 press the wafer by a width of 1.5 mm or greater, whereby the clamp ring is prevented from being deviated from the wafer. If the width of a first abutting section 4 is less than 1.5 mm, where a transfer margin is taken into consideration, then it becomes difficult to reliably press a wafer.

Further, in the second fixing section 3 other than the first fixing section 2, since the width of the second abutting section 6 is less than 1.5 mm, it is possible to process a larger area on the main surface of the wafer. Furthermore, if the width of the second abutting section 6 is 1.5 mm or greater, then the processible area becomes smaller.

In addition, since the abutting part is provided to correspond to the entire periphery of the wafer, it is possible to reduce a probability of chipping, without concentrating stress to only one point of the outer periphery of the wafer. Also, since the entire periphery of the wafer is pressed by using the clamp ring, even if slight transfer misalignment occurs, it is possible to reliably fix the wafer using the clamp ring. Further, since the entire periphery of the wafer is protected by the abutting part, sputter particles are prevented from spreading to the stage side while the film is deposited.

Furthermore, the widths of the brim sections are ensured to be 2.5 times or more than the heights of the brim sections (“L2≧2.5×H1” and “L2 24 2.5×H2”). Therefore, while a film is deposited, sputter particles are prevented from spreading to the contact portion between the abutting part and the wafer, and the conglutination of the wafer and the clamp ring is thus prevented. If the width of the brim part is less than 2.5 times the height of the brim part, then sputter particles may spread to the contact portion between the abutting part and the wafer, which easily causes easy conglutination of the wafer and the clamp ring.

As described above, if the clamp ring according to the exemplary embodiment is used, then it is possible to reliably fix the wafer without limiting the area where a film depositing process can be performed. Further, it is possible to prevent chipping and conglutinating the wafer and the clamp ring.

Also, in general, a cut used to align the wafer, which is called a “notch”, is formed at one portion of the outer periphery of a wafer. In the clamp ring main body 1 shown in FIG. 1, a V-shaped notch is formed in the wafer 10. A second fixing section 3 of the fixing part 30 is formed to be convex so that the notch is covered. Therefore, the width of the second fixing section 3 becomes broader in the vicinity of the notch, and on the contrary, the width of the second fixing section 3 becomes narrower (nearly zero) in the vicinity of the vertex of the V-shape. On the other hand, the inner periphery of the clamp ring main body 1 may have a shape reflecting the shape of the notch of the wafer. In other words, the second fixing section 3 may be formed with a constant width except for only a portion corresponding to the notch which protrudes to the inside of the wafer. Such a shape makes it possible to increase the film depositing area with less stress concentration.

Further, it is noted that Applicant's intent is to encompass equivalents of all claim elements, even if amended later during prosecution.

What is claimed is:

1. A clamp ring for a wafer which presses the wafer from a side of a main surface of the wafer to fix the wafer when a film is deposited on the main surface of the wafer, the clamp ring comprising:
an abutting part which abuts on an entire outer periphery of the main surface of the wafer when the wafer is fixed; and
a brim part which extends from an upper part of the abutting part to an inside of the wafer so as not to abut on the main surface,
wherein the abutting part includes a first abutting section and a second abutting section, and
wherein a width of the first abutting section in a radial direction is greater than a width of the second abutting section in a radial direction.

2. The clamp ring for a wafer according to claim 1,
wherein the width of the first abutting section in the radial direction is equal to or greater than 1.5 mm, and
wherein the width of the second abutting section in the radial direction is less than 1.5 mm.

3. The clamp ring for a wafer according to claim 1,
wherein the brim part includes:
a first brim section which extends from the upper part of the first abutting section to the inside of the wafer; and
a second brim section which extends from the upper part of the second abutting section to the inside of the wafer,
wherein the height of the first brim section from the main surface when the wafer is fixed is H1, and the width L2 of the first brim section in a radial direction is expressed as L2≧2.5×H1.

4. The clamp ring for a wafer according to claim 1, wherein a plurality of the first abutting sections are provided.

5. A method of manufacturing a semiconductor apparatus, comprising:
fixing a wafer by using a clamp ring;
the clamp ring comprising:
an abutting part which abuts on an entire outer periphery of a main surface of the wafer when the wafer is fixed, the abutting part including a first abutting section and a second abutting section, a width of the first abutting section in a radial direction being greater than a width of the second abutting section in a radial direction; and
a brim part which extends from an upper part of the abutting part to an inside of the wafer so as not to abut on the main surface; and
depositing a film on the main surface of the fixed wafer.

6. The method of manufacturing a semiconductor apparatus according to claim 5, wherein, in the depositing of the film, the film is deposited by sputtering.

7. A clamp ring, comprising:
a ring having a hole;
an abutting portion which projects from an entire circumference defining the hole of the ring toward a center of the hole to adjust a wafer, the abutting portion having an annular surface for attaching to a surface of the wafer, the annular surface including a first portion of a first width from an edge of the circumference toward the center of the hole and a second portion of a second width from the edge of the circumference toward the center of the hole, the first width being greater than the second width; and
a brim portion circularly provided in the hole to project from the abutting portion, the brim portion being apart from the surface of the wafer when the wafer is attached to the annular surface of the abutting portion.

8. The clamp ring as claimed in claim 7, wherein the abutting portion includes a notch portion.

9. The clamp ring as claimed in claim 7, wherein the annular surface having the first width is less than 50% of the entire circumference.
